(19) United States
(12) Patent Application Publication
(10) Pub. No.: US 2025/0321573 A1
(43) Pub. Date: Oct. 16, 2025

(54) AUTOMATIC HANDLING SYSTEM AND METHOD OF OPERATING THE SAME

(71) Applicant: NANYA TECHNOLOGY CORPORATION, New Taipei City (TW)

(72) Inventors: Chi Ming PAN, New Taipei City (TW); Jih-Cheng HUANG, New Taipei City (TW)

(21) Appl. No.: 18/636,260

(22) Filed: Apr. 16, 2024

(51) Int. Cl. G05B 23/02; H01L 21/67; H01L 21/673

(52) U.S. Cl. CPC G05B 23/027; G05B 23/0272; H01L 21/67276; H01L 21/67356; G05B 2219/45031

(57) ABSTRACT

The present disclosure provides a method of operating an automatic handling system. The method includes: controlling a handling device to move forward to a load port of a production equipment; receiving a signal of a load request by a receiver of the handling device; controlling an image capturing device of the handling device to capture an image of the load port; determining whether the receiver receives the signal of the load request; and determining whether there is any abnormal condition in the load port.

### BACKGROUND

### Field of Invention

The present invention relates to an automatic handling system and a method of operating the same.

### Description of Related Art

Automatic handling equipment of semiconductor (e.g., overhead hoist transport (OHT) or automatic guided vehicle (AGV)) is configured to pick and place materials (e.g., front opening unified pod (FOUP) or front opening shipping box (FOSB)) on production machine. The OHT is the mainstream transportation equipment used in semiconductor industry, because the OHT is installed in the air and can effectively improve the utilization of factory space.

When the automatic handling equipment (e.g., the OHT) is to pick and place the materials on production machine, the automatic handling equipment must communicate through a certain mechanism of interlocking interface to avoid picking and placing materials under unsafe conditions. Generally, semiconductor equipment follows the SEMI E84, in which E84 sensors (with input/output control signals in parallel) are installed on both the automatic handling equipment and the production machine, and in which the infrared light signals of the E84 sensors at close distances are used for interlocking communication.

Based on the above description, in semiconductor factories that are equipped with the OHT, it is needed to install routings of the E84 sensors by pulling the routings from the production machine end to OHT track end. Hence, when the OHT is to pick and place the materials on the production machine, the interlocking communication is carried out through the E84 sensors installed on the OHT and the E84 sensors installed on the production machine.

Thousands of production machines are commonly utilized in semiconductor factories, and each of the production machines has an average of about 3 pick-and-place ports. The E84 sensors must be installed on the track corresponded to each of the pick and place ports, so there will be about three thousands E84 sensor cables connected between the production machine end to the OHT track end. In addition to the fact that these cables are prone to spatial interference, the cost of these installation and the E84 sensors themselves is also quite high.

Therefore, how to propose an automatic handling system and a method of operating the same that can reduce spatial interference of interlaced cables and ensure the safety during material transportation is one of the problems that the industry urgently wants to invest in research and development resources to solve.

### SUMMARY

In view of this, one purpose of the present disclosure is to provide an automatic handling system and a method of operating the same can solve the aforementioned problems.

In order to achieve the above objective, according to an embodiment of the present disclosure, a method of operating an automatic handling system includes: controlling a handling device to move forward to a load port of a production equipment; receiving a signal of a load request by a receiver of the handling device; controlling an image capturing device of the handling device to capture an image of the load port; determining whether the receiver receives the signal of the load request; and determining whether there is any abnormal condition in the load port.

In one or more embodiments of the present disclosure, controlling the image capturing device of the handling device to capture the image of the load port is performed after receiving the signal of the load request by the receiver of the handling device.

In one or more embodiments of the present disclosure, the image capturing device of the handling device captures the image of a status light disposed on the load port.

In one or more embodiments of the present disclosure, determining whether the receiver receives the signal of the load request further includes: determining whether a visual signal of the status light conforms to the signal of the load request; confirming the receiver receiving the signal of the load request if the visual signal of the status light conforms to the signal of the load request; and issuing an alarm if the visual signal of the status light does not conform to the signal of the load request.

In one or more embodiments of the present disclosure, determining whether there is any abnormal condition in the load port is performed after determining whether the receiver receives the signal of the load request.

In one or more embodiments of the present disclosure, determining whether there is any abnormal condition in the load port further includes processing the image of the load port.

In one or more embodiments of the present disclosure, determining whether there is any abnormal condition in the load port further includes: determining whether the image of the load port includes a foreign object; confirming there is no abnormal condition in the load port if there is no foreign object within a range of the load port; and issuing an alarm if there is the foreign object within a range of the load port.

In one or more embodiments of the present disclosure, the method further includes permitting the handling device to place a material box to the load port performed after determining whether there is any abnormal condition in the load port.

In order to achieve the above objective, according to an embodiment of the present disclosure, a method of operating an automatic handling system includes: controlling a handling device to move forward to a load port of a production equipment; receiving a signal of an unload request by a receiver of the handling device; controlling an image capturing device of the handling device to capture an image of the load port; determining whether the receiver receives the signal of the unload request; and determining whether there is any abnormal condition in the load port.

In one or more embodiments of the present disclosure, controlling the image capturing device of the handling device to capture the image of the load port is performed after receiving the signal of the unload request by the receiver of the handling device.

In one or more embodiments of the present disclosure, the image capturing device of the handling device captures the image of a status light disposed on the load port.

In one or more embodiments of the present disclosure, determining whether the receiver receives the signal of the unload request further includes: determining whether a visual signal of the status light conforms to the signal of the unload request; confirming the receiver receiving the signal of the unload request if the visual signal of the status light conforms to the signal of the unload request; and issuing an alarm if the visual signal of the status light does not conform to the signal of the unload request.

In one or more embodiments of the present disclosure, determining whether there is any abnormal condition in the load port is performed after determining whether the receiver receives the signal of the unload request.

In one or more embodiments of the present disclosure, determining whether there is any abnormal condition in the load port further includes processing the image of the load port.

In one or more embodiments of the present disclosure, determining whether there is any abnormal condition in the load port further includes: determining whether the image of the load port includes a foreign object; confirming there is no abnormal condition in the load port if there is no foreign object within a range of the load port; and issuing an alarm if there is the foreign object within a range of the load port.

In one or more embodiments of the present disclosure, the method further includes permitting the handling device to pick a material box from the load port performed after determining whether there is any abnormal condition in the load port.

In order to achieve the above objective, according to an embodiment of the present disclosure, an automatic handling system includes a production equipment, a handling device, and a processing unit. The production equipment includes a load port and a status light disposed on the load port and configured to display a plurality of visual signals. The visual signals include an allowable-to-load signal, an unallowable-to-load signal, an allowable-to-unload signal, and an unallowable-to-unload signal. The handling device includes an image capturing device configured to capture an image of the load port. The processing unit is electrically or communicatively connected to the production equipment and the handling device. The processing unit is configured to: control the handling device to move forward to the load port of the production equipment; receive a signal of a load request or an unload request by a receiver of the handling device; control the image capturing device of the handling device to capture the image of the load port; determine whether the receiver receives the signal of the load request or the unload request; and determine whether there is any abnormal condition in the load port.

In one or more embodiments of the present disclosure, the handling device further includes a main body and a clamping portion. The image capturing device is disposed on the main body. The clamping portion is connected to the main body and configured to clamp a material box.

In one or more embodiments of the present disclosure, the processing unit is further configured to: determine whether the visual signals of the status light conform to the signal of the load request or the unload request; confirm the receiver receiving the signal of the load request or the unload request if the visual signals of the status light conform to the signal of the load request or the unload request; and issue an alarm if the visual signals of the status light do not conform to the signal of the load request or the unload request.

In one or more embodiments of the present disclosure, the processing unit is further configured to: determine whether the image of the load port includes a foreign object; confirm there is no abnormal condition in the load port if there is no foreign object within a range of the load port; and issue an alarm if there is the foreign object within a range of the load port.

In summary, in the automatic handling system and the method of operating the same of the present disclosure, since the processing unit can process the image of the status light of the load port, the automatic handling system double-confirms the command of the load request or the unload request, thereby decreasing the overkill rate during loading process and unloading process. In the automatic handling system and the method of operating the same of the present disclosure, since the processing unit can further determine whether there is any abnormal condition in the load port by processing the image of the load port, the automatic handling system may verify the condition within the range of the load port more accurately. In the automatic handling system and the method of operating the same of the present disclosure, since the handling device and the production equipment communicate by interlock interface aided by the image capturing device, the handling device can obtain the condition of the load port without approaching the production equipment, thereby achieving the effects of identifying the foreign objects in the load port and wireless communication between the handling device and the production equipment. Overall, the method of operating the automatic handling system of the present disclosure not only improves the accuracy of determining whether the handling device is allowed to load or unload the material box but also solves the spatial interference problem of interlaced cables.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a schematic diagram of an automatic handling system in accordance with an embodiment of the present disclosure;

FIG. 2 is a schematic diagram of the automatic handling system in accordance with an embodiment of the present disclosure;

FIG. 3 is a functional block diagram of the automatic handling system in accordance with an embodiment of the present disclosure;

FIG. 4 is a flow chart of a method of operating the automatic handling system in accordance with an embodiment of the present disclosure; and

FIG. 5 is a flow chart of a method of operating the automatic handling system in accordance with an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The system may be otherwise oriented (rotated 90 degrees or at other orientations) and the spatially relative descriptors used herein may likewise be interpreted accordingly.

As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

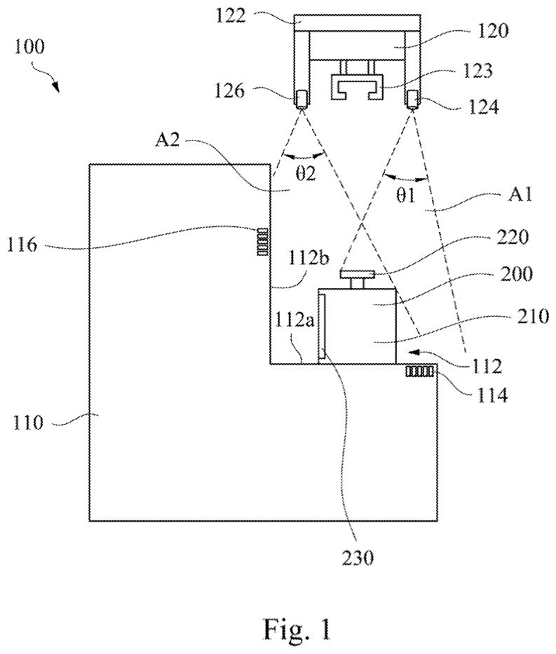

Reference is made to FIG. 1. FIG. 1 is a schematic diagram of an automatic handling system 100 in accordance with an embodiment of the present disclosure. In this embodiment, the automatic handling system 100 includes a production equipment 110 and a handling device 120. The production equipment 110 is electrically and communicatively connected to the handling device 120. The production equipment 110 is configured to accommodate a material box 200. The production equipment 110 includes a load port 112, a first status light 114, and a second status light 116. More specifically, the load port 112 is a recessed cavity on the production equipment 110. The load port 112 is configured to accommodate the material box 200, as shown in FIG. 1. The load port 112 provides a location where the handling device 120 load or unload (i.e., pick and place) the material box 200. In some embodiments, the load port 112 has a horizontal surface 112a and a vertical surface 112b. The first status light 114 is disposed on the horizontal surface 112a of the load port 112. The second status light 116 is disposed on the vertical surface 112b of the load port 112. The first status light 114 and the second status light 116 are respectively disposed buried beneath the horizontal surface 112a and the vertical surface 112b, and the a portion of the horizontal surface 112a and a portion of the vertical surface 112b respectively corresponded to the first status light 114 and the second status light 116 are transparent such that the first status light 114 and the second status light 116 are visible. The first status light 114 and the second status light 116 are configured to display a plurality of visual signals. More specifically, the aforementioned visual signals include an allowable-to-load signal, an unallowable-to-load signal, an allowable-to-unload signal, and an unallowable-to-unload signal.

Reference is made again to FIG. 1. In this embodiment, the handling device 120 is configured to pick the material box 200 from the load port 112 of the production equipment 110 and place the material box 200 to the load port 112 of the production equipment 110. As shown in FIG. 1, the handling device 120 includes a main body 122, a clamping portion 123, a first image capturing device 124, and a second image capturing device 126. The clamping portion 123 is connected to the main body 122. The clamping portion 123 is configured to clamp the material box 200. The first image capturing device 124 and the second image capturing device 126 are disposed on the main body 122. The first image capturing device 124 and the second image capturing device 126 are configured to capture an image of the load port 112. In some embodiments, the first image capturing device 124 and the second image capturing device 126 capture the image of the first status light 114 and the second status light 116 disposed on the load port 112. As shown in FIG. 1, the first image capturing device 124 has a first field of view A1 at a first angle θ1, and the second image capturing device 126 has a second field of view A2 at a second angle θ2. Each of the first field of view A1 and the second field of view A2 covers the material box 200 and at least one of the first status light 114 and the second status light 116. In other words, the image of the load port 112 captured by the first image capturing device 124 or the second image capturing device 126 includes the material box 200 and at least one of the first status light 114 and the second status light 116.

In some embodiments, the first field of view A1 covers the material box 200 and the first status light 114, and the second field of view A2 covers the material box 200 and the second status light 116. In some embodiments, the image of the load port 112 captured by the first image capturing device 124 includes the material box 200 and the first status light 114, and the image of the load port 112 captured by the second image capturing device 126 includes the material box 200 and the second status light 116.

As shown in FIG. 1, the material box 200 includes a box body 210, a flange 220, and a door portion 230. The flange 220 is disposed on the box body 210. In some embodiments, the flange 220 is disposed on a top surface of the box body 210. The door portion 230 is disposed on the box body 210. The door portion 230 is separated from the flange 220. In some embodiments, the door portion 230 is disposed on a side surface of the box body 210.

In some embodiments, the production equipment 110 further includes an engaging structure (not depicted) disposed on the horizontal surface 112a of the load port 112 and located near a location where the material box 200 is placed. The engaging structure is configured to be engage with the material box 200.

In a usage scenario, as the handling device 120 is going to pick the material box 200 from the load port 112, the engaging structure is loosened, so that the first status light 114 and the second status light 116 display the visual signals, such as the allowable-to-unload signal, and the material box 200 is allowed to be clamped by the clamping portion 123 of the handling device 120.

As shown in FIG. 1, in a usage scenario, as the handling device 120 is going to place the material box 200 to the load port 112, the first status light 114 and the second status light 116 display the visual signals (such as the allowable-to-load signal), the material box 200 is allowed to be placed by the handling device 120, and the engaging structure is fastened.

In some embodiments, the allowable-to-load signal, the unallowable-to-load signal, the allowable-to-unload signal, and the unallowable-to-unload signal may present in form of visible color light with different color. For instance, the allowable-to-load signal and the allowable-to-unload signal may present in green light or any suitable color light, whereas the unallowable-to-load signal and the unallowable-to-unload signal may present in red light or any suitable color light which is distinguished from the allowable-to-load signal and the allowable-to-unload signal. However, the present disclosure is not intended to limit the way in which the allowable-to-load signal, the unallowable-to-load signal, the allowable-to-unload signal, and the unallowable-to-unload signal present.

In some embodiments, the material box 200 may be a front opening unified pod (FOUP), a front opening shipping box (FOSB) or other possible transported object. In some embodiments, the FOUP or the FOSB may carry one or more product wafers.

In some embodiments, the first status light 114 and the second status light 116 may be light emitting diode (LED) or any suitable light source. The present disclosure is not intended to limit the type of the first status light 114 and the second status light 116.

In some embodiments, the first image capturing device 124 and the second image capturing device 126 may be camera or any suitable device which is configured to capture an image. The present disclosure is not intended to limit the type of the first image capturing device 124 and the second image capturing device 126.

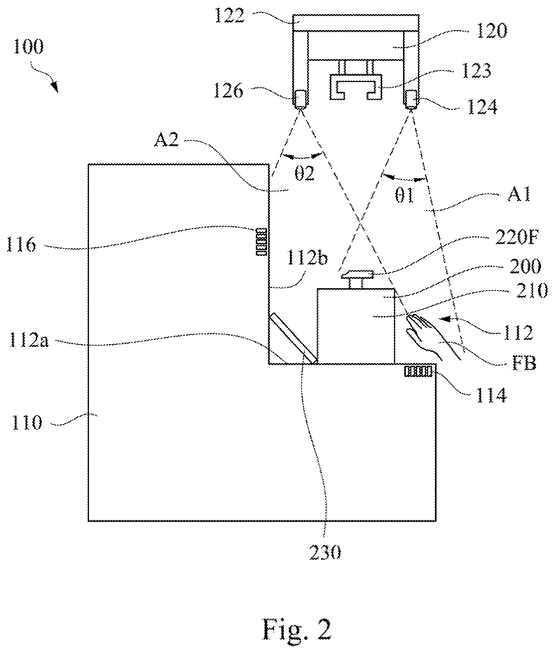

Reference is made to FIG. 2. FIG. 2 is a schematic diagram of the automatic handling system 100 in accordance with an embodiment of the present disclosure. The structural configuration as shown in FIG. 2 is similar to the structural configuration as shown in FIG. 1. The difference between the structural configuration as shown in FIG. 2 and the structural configuration as shown in FIG. 1 is that the material box 200 as shown in FIG. 2 includes a damaged flange 220F instead of the flange 220 as shown in FIG. 1. In addition, the door portion 230 drops from the box body 210, and a foreign object FB is within a range of the load port 112, as shown in FIG. 2.

In some embodiments, the foreign object FB may be biological features of creatures (e.g., a finger, an arm, a palm, foot, head, etc.), unrelated objects, or any possible object which is exclusive of the material box 200.

As shown in FIG. 2, in a usage scenario, as the handling device 120 is going to pick the material box 200 from the load port 112, the aforementioned engaging structure is loosened but the material box 200 has the damaged flange 220F and the dropping door portion 230. In addition, the foreign object FB enters the range of the load port 112. Hence, the first status light 114 and the second status light 116 display the visual signals, such as the unallowable-to-unload signal, and the material box 200 is not allowed to be clamped by the clamping portion 123 of the handling device 120.

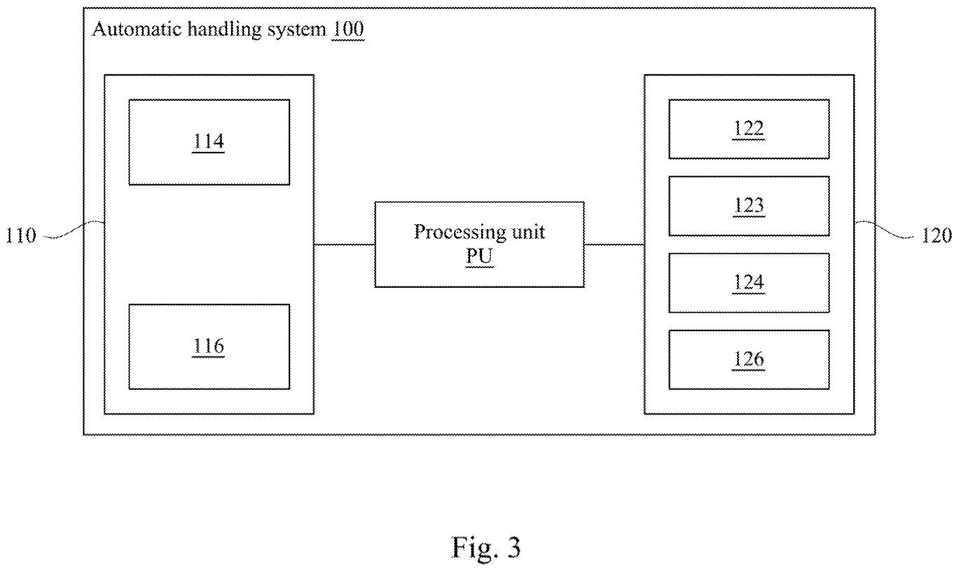

Reference is made to FIG. 3. FIG. 3 is a functional block diagram of the automatic handling system 100 in accordance with an embodiment of the present disclosure. In this embodiment, the automatic handling system 100 further includes a processing unit PU, as shown in FIG. 3. The processing unit PU is electrically and communicatively connected to the production equipment 110 and the handling device 120. The processing unit PU is configured to control the first status light 114 and the second status light 116 to display the visual signals. The processing unit is further configured to control the handling device 120 to move forward to or backward from the production equipment 110. The processing unit PU is further configured to send a signal of a load request or a signal of an unload request to the handling device 120. The processing unit PU is configured to control the clamping portion 123 to clamp the material box 200. The processing unit PU is further configured to control the first image capturing device 124 and the second image capturing device 126 of the handling device 120 to capture the image of the load port 112 of the production equipment 110. The processing unit is further configured to determining whether the handling device 120 receives the signal of the load request or the signal of the unload request. The processing unit PU is further configured to determining whether there is any abnormal condition (e.g., the damaged flange 220F, the dropping door portion 230, the foreign object FB, etc.) in the load port 112.

In some embodiments, the handling device 120 has a receiver (not depicted) configured to receive the signal of the load request or the signal of the unload request.

In some embodiments, determining whether there is any abnormal condition in the load port 112 further includes processing the image of the load port 112.

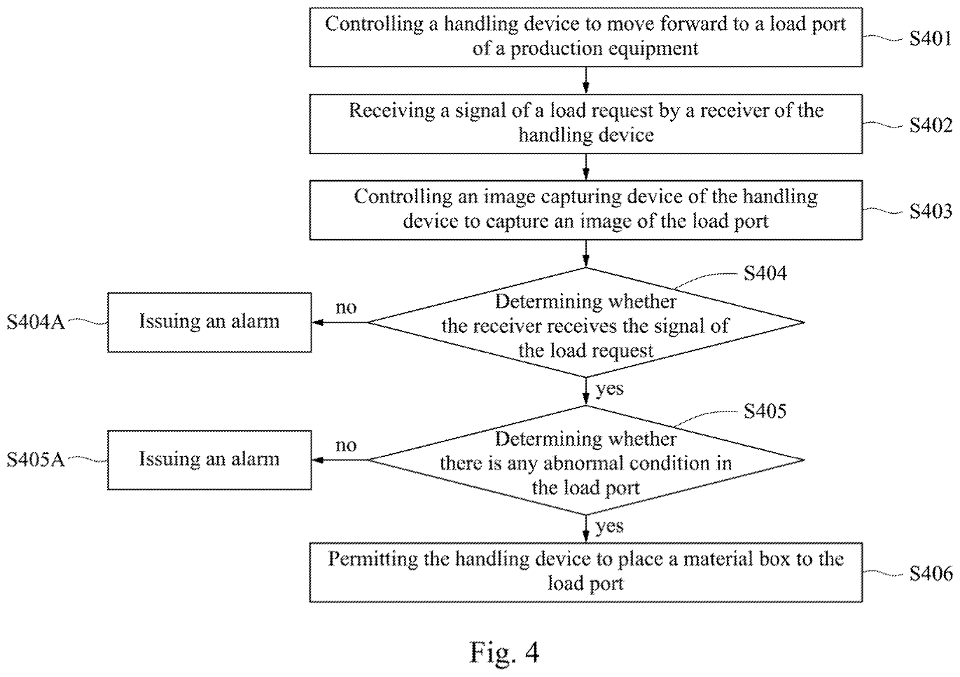

Reference is made to FIG. 4. FIG. 4 is a flow chart of a method of operating the automatic handling system 100 in accordance with an embodiment of the present disclosure. FIG. 4 shows the flow chart of a process of the handling device 120 placing the material box 200 to the load port 112. The method shown in FIG. 4 includes a step S401, a step S402, a step S403, a step S404, a step S404A, a step S405, a step S405A, and a step S406. Please refer to FIG. 1, FIG. 2, and FIG. 4 for better understanding the step S401, the step S402, the step S403, the step S404, the step S404A, the step S405, the step S405A, and the step S406.

Step S401, step S402, step S403, step S404, step S404A, step S405, step S405A, and step S406 are described in detail below.

Step S401: controlling the handling device to move forward to the load port of the production equipment.

Reference is made to FIG. 1 and FIG. 4. In this embodiment, the handling device 120 is controlled by the processing unit PU, and the processing unit PU controls the handling device 120 to move forward to the load port 112 of the production equipment 110. More specifically, the handling device 120 moves forward to a location over the load port 112 of the production equipment 110 through a sky track.

In some embodiments, the method shown in FIG. 4 further includes a step of sending a transport command to the handling device 120. More specifically, the processing unit PU is configured to send the transport command to the handling device 120. In some embodiments, the step of sending the transport command to the handling device 120 is performed before the step of controlling the handling device 120 to move forward to the load port 112 of the production equipment 110.

In a usage scenario, the handling device 120 carries the material box 200 and moves forward to the location over the load port 112 of the production equipment 110 after the processing unit PU sends the transport command to the handling device 120.

Step S402: receiving the signal of the load request by the receiver of the handling device.

Reference is made again to FIG. 1 and FIG. 4. In this embodiment, the receiver of the handling device 120 receives the signal of the load request from the processing unit PU. More specifically, the processing unit PU sends the signal of the load request to the handling device 120. In some embodiments, the step of receiving the signal of the load request by the receiver of the handling device 120 (i.e., step S402) is performed after the step of controlling the handling device 120 to move forward to the load port 112 of the production equipment 110 (i.e., step S401).

In a usage scenario, the handling device 120 moves forward to the location over the load port 112 of the production equipment 110. Next, the receiver of the handling device 120 receives the signal of the load request.

Step S403: controlling the image capturing device of the handling device to capture the image of the load port.

In this embodiment, the first image capturing device 124 and the second image capturing device 126 of the handling device 120 are controlled by the processing device PU, and the processing unit PU controls the first image capturing device 124 and the second image capturing device 126 of the handling device 120 to capture the image of the load port 112. More specifically, the first image capturing device 124 or the second image capturing device 126 captures the image including at least one of a visual signal displayed by the first status light 114 and a visual signal displayed by the second status light 116.

In some embodiments, the step of controlling the first image capturing device 124 and the second image capturing device 126 of the handling device 120 to capture the image of the load port 112 (i.e., step S403) is performed after the step of receiving the signal of the load request by the receiver of the handling device 120 (i.e., step S402).

In a usage scenario, the receiver of the handling device 120 receives the signal of the load request. Next, the first image capturing device 124 captures the image including the visual signal displayed by the first status light 114. The second image capturing device 126 captures the image including the visual signal displayed by the second status light 116.

In some embodiments, both the first image capturing device 124 and the second image capturing device 126 capture the image including the visual signal displayed by the first status light 114 and the visual signal displayed by the second status light 116.

Step S404: determining whether the receiver receives the signal of the load request.

In this embodiment, the processing unit PU determines whether the receiver of the handling device 120 receives the signal of the load request. More specifically, the step of determining whether the receiver receives the signal of the load request includes identifying the visual signal of the first status light 114 and the visual signal of the second status light 116.

In some embodiments, the step of determining whether the receiver receives the signal of the load request (i.e., step S404) is performed after the step of controlling the first image capturing device 124 and the second image capturing device 126 of the handling device 120 to capture the image of the load port 112 (i.e., step S403).

In some embodiments, the step of determining whether the receiver receives the signal of the load request further includes determining whether the visual signal of the first status light 114 and the visual signal of the second status light 116 conform to the signal of the load request. More specifically, the processing unit PU determines whether the engaging structure is loosened. The load request is sent to the handling device 120 if the engaging structure is loosened. Then, the processing unit PU determines whether the visual signal of the first status light 114 and the visual signal of the second status light 116 conform to the signal of the load request or not.

In a usage scenario, the first image capturing device 124 captures the image including the visual signal displayed by the first status light 114, and the second image capturing device 126 captures the image including the visual signal displayed by the second status light 116. Next, the processing unit PU compares the visual signals of the first status light 114 and the second status light 116 with the signal of the load request to confirm the coherence among the visual signal of the first status light 114, the visual signal of the second status light 116, and the signal of the load request.

Step S404A: issuing an alarm.

Reference is made again to FIG. 2 and FIG. 4. In this embodiment, if the visual signal of the first status light 114 and the visual signal of the second status light 116 do not conform to the signal of the load request, the processing unit PU issues an alarm. In some embodiments, the processing unit PU issues an alarm and terminates the load request.

In some embodiments, the alarm may be issued in a way of push notification, a text message, siren, or any suitable way or approach.

In a usage scenario, the processing unit PU determines whether the visual signal of the first status light 114 and the visual signal of the second status light 116 conform to the signal of the load request or not. For instance, if the processing unit PU sends the load request but the first status light 114 and the second status light 116 display the unallowable-to-load signal due to the engaging structure being fastened, the processing unit PU issues the alarm and terminates the load request.

Step S405: determining whether there is any abnormal condition in the load port.

Reference is made again to FIG. 1, FIG. 2, and FIG. 4. In this embodiment, if the visual signal of the first status light 114 and the visual signal of the second status light 116 conform to the signal of the load request, the processing unit PU confirms that the receiver of the handling device 120 does receive the signal of the load request. In a usage scenario, if the processing unit PU sends the load request and the first status light 114 and the second status light 116 display the allowable-to-load signal, the processing unit PU continues to perform a step of determining whether there is any abnormal condition in the load port 112 (i.e., step S405), for instance. More specifically, the step of determining whether there is any abnormal condition in the load port 112 includes identifying whether the image of the load port 112 records any abnormal condition in the load port 112.

In some embodiments, the step of determining whether there is any abnormal condition in the load port 112 (i.e., step S405) is performed after the step of determining whether the receiver receives the signal of the load request (i.e., step S404).

In some other embodiments, the step of determining whether there is any abnormal condition in the load port 112 (i.e., step S405) is performed before the step of determining whether the receiver receives the signal of the load request (i.e., step S404).

In some embodiments, the step of determining whether there is any abnormal condition in the load port 112 further includes determining whether the image of the load port 112 includes the foreign object FB. More specifically, the processing unit PU determines whether the foreign object FB enters the range of the load port 112.

In a usage scenario, the processing unit PU confirms that the handling device 120 exactly receives the signal of the load request. Next, the processing unit PU identifies whether there is the foreign object FB within the range of the load port 112 or not.

Step S405A: issuing an alarm.

Reference is made again to FIG. 2 and FIG. 4. In this embodiment, if there is the foreign object FB within the range of the load port 112, the processing unit PU issues an alarm. In some embodiments, the processing unit PU issues an alarm and terminates the load request.

In a usage scenario, the processing unit PU determines whether there is the foreign object FB within the range of the load port 112 or not. For instance, if the first status light 114 and the second status light 116 display the allowable-to-load signal but there is the foreign object FB within the range of the load port 112, the processing unit PU issues the alarm and terminates the load request.

Step S406: permitting the handling device to place the material box to the load port.

Reference is made again to FIG. 1 and FIG. 4. In this embodiment, if there is no foreign object FB within the range of the load port 112, the processing unit PU confirms that there is no abnormal condition in the load port 112. In a usage scenario, if the first status light 114 and the second status light 116 display the allowable-to-load signal and there is no foreign object FB within the range of the load port 112, the processing unit PU performs a step of permitting the handling device 120 to place the material box 200 to the load port 112 (i.e., step S406), for instance. More specifically, the step of permitting the handling device 120 to place the material box 200 to the load port 112 includes controlling the clamping portion 123 to place the material box 200 onto the load port 112.

In some embodiments, the handling device 120 places the material box 200 to the load port 112 such that the clamping portion 123 moves from a location near the main body 122 to the load port 112 when carrying the material box 200. In some embodiments, the handling device 120 places the material box 200 to the load port 112 such that the clamping portion 123 and the material box 200 together move from the location near the main body 122 to the load port 112.

In some embodiments, the step of permitting the handling device 120 to place the material box 200 to the load port 112 (i.e., step S406) is performed after the step of determining whether there is any abnormal condition in the load port 112 (i.e., step S405).

In a usage scenario, the processing unit PU confirms there is no abnormal condition in the load port 112. Next, the clamping portion 123 places the material box 200 onto the load port 112.

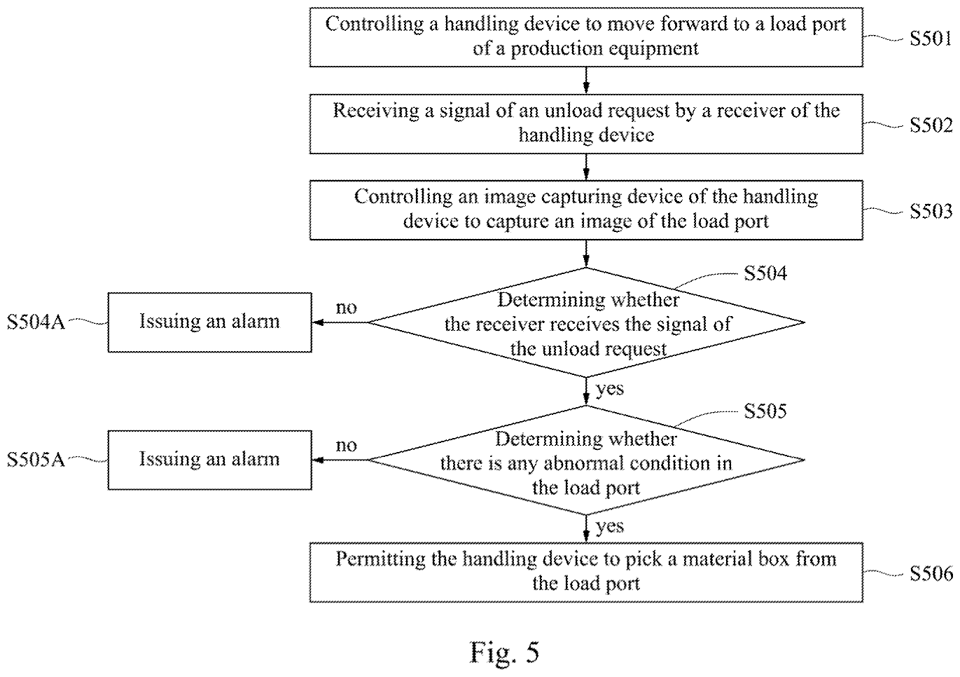

Reference is made to FIG. 5. FIG. 5 is a flow chart of a method of operating the automatic handling system 100 in accordance with an embodiment of the present disclosure. FIG. 5 shows the flow chart of a process of the handling device 120 picking the material box 200 from the load port 112. The method shown in FIG. 5 includes a step S501, a step S502, a step S503, a step S504, a step S504A, a step S505, a step S505A, and a step S506. Please refer to FIG. 1, FIG. 2, and FIG. 5 for better understanding the step S501, the step S502, the step S503, the step S504, the step S504A, the step S505, the step S505A, and the step S506.

Step S501, step S502, step S503, step S504, step S504A, step S505, step S505A, and step S506 are described in detail below.

Step S501: controlling the handling device to move forward to the load port of the production equipment.

Reference is made to FIG. 1 and FIG. 5. In this embodiment, the handling device 120 is controlled by the processing unit PU, and the processing unit PU controls the handling device 120 to move forward to the load port 112 of the production equipment 110. More specifically, the handling device 120 moves forward to the location over the load port 112 of the production equipment 110 through the sky track.

In some embodiments, the method shown in FIG. 5 further includes a step of sending a transport command to the handling device 120. More specifically, the processing unit PU is configured to send the transport command to the handling device 120. In some embodiments, the step of sending the transport command to the handling device 120 is performed before the step of controlling the handling device 120 to move forward to the load port 112 of the production equipment 110.

Step S502: receiving the signal of the unload request by the receiver of the handling device.

Reference is made again to FIG. 1 and FIG. 5. In this embodiment, the receiver of the handling device 120 receives the signal of the unload request from the processing unit PU. More specifically, the processing unit PU sends the signal of the unload request to the handling device 120. In some embodiments, the step of receiving the signal of the unload request by the receiver of the handling device 120 (i.e., step S502) is performed after the step of controlling the handling device 120 to move forward to the load port 112 of the production equipment 110 (i.e., step S501).

In a usage scenario, the handling device 120 moves forward to the location over the load port 112 of the production equipment 110. Next, the receiver of the handling device 120 receives the signal of the unload request.

Step S503: controlling the image capturing device of the handling device to capture the image of the load port.

Reference is made again to FIG. 1 and FIG. 5. In this embodiment, the first image capturing device 124 and the second image capturing device 126 of the handling device 120 are controlled by the processing device PU, and the processing unit PU controls the first image capturing device 124 and the second image capturing device 126 of the handling device 120 to capture the image of the load port 112. More specifically, the first image capturing device 124 or the second image capturing device 126 captures the image including the material box 200 and at least one of a visual signal displayed by the first status light 114 and a visual signal displayed by the second status light 116.

In some embodiments, the step of controlling the first image capturing device 124 and the second image capturing device 126 of the handling device 120 to capture the image of the load port 112 (i.e., step S503) is performed after the step of receiving the signal of the unload request by the receiver of the handling device 120 (i.e., step S502).

In a usage scenario, the receiver of the handling device 120 receives the signal of the unload request. Next, the first image capturing device 124 captures the image including the material box 200 and the visual signal displayed by the first status light 114. The second image capturing device 126 captures the image including the material box 200 and the visual signal displayed by the second status light 116.

In some embodiments, both the first image capturing device 124 and the second image capturing device 126 capture the image including the material box 200 and the visual signal displayed by the first status light 114 and the visual signal displayed by the second status light 116.

Step S504: determining whether the receiver receives the signal of the unload request.

Reference is made again to FIG. 1 and FIG. 5. In this embodiment, the processing unit PU determines whether the receiver of the handling devices 120 receives the signal of the unload request. More specifically, the step of determining whether the receiver receives the signal of the unload request includes identifying the visual signal of the first status light 114 and the visual signal of the second status light 116.

In some embodiments, the step of determining whether the receiver receives the signal of the unload request (i.e., step S504) is performed after the step of controlling the first image capturing device 124 and the second image capturing device 126 of the handling device 120 to capture the image of the load port 112 (i.e., step S503).

In some embodiments, the step of determining whether the receiver receives the signal of the unload request further includes determining whether the visual signal of the first status light 114 and the visual signal of the second status light 116 conform to the signal of the unload request. More specifically, the processing unit PU determines whether the engaging structure is loosened. The unload request is sent to the handling device 120 if the engaging structure is loosened. Then, the processing unit PU determines whether the visual signal of the first status light 114 and the visual signal of the second status light 116 conform to the signal of the unload request or not.

In a usage scenario, the first image capturing device 124 captures the image including the material box 200 and the visual signal displayed by the first status light 114 and the visual signal displayed by the second status light 116, and the second image capturing device 126 captures the image including the material box 200 and the visual signal displayed by the second status light 116. Next, the processing unit PU compares the visual signals of the first status light 114 and the second status light 116 with the signal of the unload request to confirm the coherence among the visual signal of the first status light 114, the visual signal of the second status light 116, and the signal of the unload request.

Step S504A: issuing an alarm.

Reference is made again to FIG. 2 and FIG. 5. In this embodiment, if the visual signal of the first status light 114 and the visual signal of the second status light 116 do not conform to the signal of the unload request, the processing unit PU issues an alarm. In some embodiments, the processing unit PU issues an alarm and terminates the unload request.

In some embodiments, the alarm may be issued in a way of push notification, a text message, siren, or any suitable way or approach.

In a usage scenario, the processing unit PU determines whether the visual signal of the first status light 114 and the visual signal of the second status light 116 conform to the signal of the unload request or not. For instance, if the processing unit PU sends the unload request but the first status light 114 and the second status light 116 display the unallowable-to-unload signal due to the engaging structure being fastened, the processing unit PU issues the alarm and terminates the unload request.

Step S505: determining whether there is any abnormal condition in the load port.

Reference is made again to FIG. 1, FIG. 2, and FIG. 5. In this embodiment, if the visual signal of the first status light 114 and the visual signal of the second status light 116 conform to the signal of the unload request, the processing unit PU confirms that the receiver of the handling device 120 does receive the signal of the unload request. In a usage scenario, if the processing unit PU sends the unload request and the first status light 114 and the second status light 116 display the allowable-to-unload signal, the processing unit PU continues to perform a step of determining whether there is any abnormal condition in the load port 112 (i.e., step S505), for instance. More specifically, the step of determining whether there is any abnormal condition in the load port 112 includes identifying whether the image of the load port 112 records any abnormal condition in the load port 112.

In some embodiments, the step of determining whether there is any abnormal condition in the load port 112 (i.e., step S505) is performed after the step of determining whether the receiver receives the signal of the unload request (i.e., step S504).

In some other embodiments, the step of determining whether there is any abnormal condition in the load port 112 (i.e., step S505) is performed before the step of determining whether the receiver receives the signal of the unload request (i.e., step S504).

In some embodiments, the step of determining whether there is any abnormal condition in the load port 112 further includes determining whether the image of the load port 112 includes the foreign object FB. In addition, the step of determining whether there is any abnormal condition in the load port 112 further includes determining whether the image of the load port 112 includes the damaged flange 220F and the dropped door portion 230. More specifically, the processing unit PU determines: whether the foreign object FB enters the range of the load port 112; whether a damage of the flange 220 occurs; and whether a dropping of the door portion 230 occurs.

In a usage scenario, the processing unit PU confirms that the handling device 120 exactly receives the signal of the unload request. Next, the processing unit PU identifies: whether there is the foreign object FB within the range of the load port 112; whether a damage of the flange 220 occurs; and whether a dropping of the door portion 230 occurs.

Step S505A: issuing an alarm.

Reference is made again to FIG. 2 and FIG. 5. In this embodiment, if at least one of the following: there is the foreign object FB within the range of the load port 112; the damage of the flange 220 occurs; and the dropping of the door portion 230 occurs, the processing unit PU issues an alarm. In some embodiments, the processing unit PU issues the alarm and terminates the unload request.

In a usage scenario, the processing unit PU determines: whether there is the foreign object FB within the range of the load port 112; whether the damage of the flange 220 occurs; and whether the dropping of the door portion 230 occurs. For instance, if the first status light 114 and the second status light 116 display the allowable-to-unload signal but at least one of the following: there is the foreign object FB within the range of the load port 112; the damage of the flange 220 occurs; and the dropping of the door portion 230 occurs, the processing unit PU issues the alarm and terminates the unload request.

Step S506: permitting the handling device to pick the material box from the load port.

Reference is made again to FIG. 1 and FIG. 5. In this embodiment, if all of the following: there is no foreign object FB within the range of the load port 112; the damage of the flange 220 does not occur; and the dropping of the door portion 230 does not occur, the processing unit PU confirms that there is no abnormal condition in the load port 112. In a usage scenario, if the first status light 114 and the second status light 116 display the allowable-to-unload signal and all of the following: there is no foreign object FB within the range of the load port 112; the damage of the flange 220 does not occur; and the dropping of the door portion 230 does not occur, the processing unit PU performs a step of permitting the handling device 120 to pick the material box 200 from the load port 112 (i.e., step S406), for instance. More specifically, the step of permitting the handling device 120 to pick the material box 200 from the load port 112 includes controlling the clamping portion 123 to pick the material box 200 from the load port 112.

In some embodiments, the handling device 120 picks the material box 200 from the load port 112 such that the clamping portion 123 moves from the load port 112 to the location near the main body 122 when carrying the material box 200. In some embodiments, the handling device 120 picks the material box 200 from the load port 112 such that the clamping portion 123 and the material box 200 together move from the load port 112 to the location near the main body 122 when carrying the material box 200.

In some embodiments, the step of permitting the handling device 120 to pick the material box 200 from the load port 112 (i.e., step S506) is performed after the step of determining whether there is any abnormal condition in the load port 112 (i.e., step S505).

In a usage scenario, the processing unit PU confirms there is no abnormal condition in the load port 112. Next, the clamping portion 123 picks the material box 200 from the load port 112.

By performing the method shown in FIG. 4 and FIG. 5 of the present disclosure, the material box 200 can be picked and placed by the handling device 120 in a safer way. In addition, the automatic handling system 100 can be constructed without conventional sensors and interlaced cables connected between the sensors, thereby solving the problem of spatial interference induced by the interlaced cables.

Based on the above discussions, it can be seen that in the automatic handling system and the method of operating the same of the present disclosure, since the processing unit can process the image of the status light of the load port, the automatic handling system double-confirms the command of the load request or the unload request, thereby decreasing the overkill rate during loading process and unloading process. In the automatic handling system and the method of operating the same of the present disclosure, since the processing unit can further determine whether there is any abnormal condition in the load port by processing the image of the load port, the automatic handling system may verify the condition within the range of the load port more accurately. In the automatic handling system and the method of operating the same of the present disclosure, since the handling device and the production equipment communicate by interlock interface aided by the image capturing device, the handling device can obtain the condition of the load port without approaching the production equipment, thereby achieving the effects of identifying the foreign objects in the load port and wireless communication between the handling device and the production equipment. Overall, the method of operating the automatic handling system of the present disclosure not only improves the accuracy of determining whether the handling device is allowed to load or unload the material box but also solves the spatial interference problem of interlaced cables.

In some embodiments, the automatic handling system 100 of the present disclosure can be applied in artificial intelligence (AI) computing and edge computing.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of operating an automatic handling system, comprising:
controlling a handling device to move forward to a load port of a production equipment;
receiving a signal of a load request by a receiver of the handling device;
controlling an image capturing device of the handling device to capture an image of the load port;
determining whether the receiver receives the signal of the load request; and
determining whether there is any abnormal condition in the load port.

2. The method of claim 1, wherein controlling the image capturing device of the handling device to capture the image of the load port is performed after receiving the signal of the load request by the receiver of the handling device.

3. The method of claim 1, wherein the image capturing device of the handling device captures the image of a status light disposed on the load port.

4. The method of claim 3, wherein determining whether the receiver receives the signal of the load request further comprises:
determining whether a visual signal of the status light conforms to the signal of the load request;
confirming the receiver receiving the signal of the load request if the visual signal of the status light conforms to the signal of the load request; and
issuing an alarm if the visual signal of the status light does not conform to the signal of the load request.

5. The method of claim 1, wherein determining whether there is any abnormal condition in the load port is performed after determining whether the receiver receives the signal of the load request.

6. The method of claim 1, wherein determining whether there is any abnormal condition in the load port further comprises processing the image of the load port.

7. The method of claim 6, wherein determining whether there is any abnormal condition in the load port further comprises:
determining whether the image of the load port comprises a foreign object;
confirming there is no abnormal condition in the load port if there is no foreign object within a range of the load port; and
issuing an alarm if there is the foreign object within a range of the load port.

8. The method of claim 1, further comprising permitting the handling device to place a material box to the load port performed after determining whether there is any abnormal condition in the load port.

9. A method of operating an automatic handling system, comprising:
controlling a handling device to move forward to a load port of a production equipment;
receiving a signal of an unload request by a receiver of the handling device;
controlling an image capturing device of the handling device to capture an image of the load port;
determining whether the receiver receives the signal of the unload request; and
determining whether there is any abnormal condition in the load port.

10. The method of claim 9, wherein controlling the image capturing device of the handling device to capture the image of the load port is performed after receiving the signal of the unload request by the receiver of the handling device.

11. The method of claim 9, wherein the image capturing device of the handling device captures the image of a status light disposed on the load port.

12. The method of claim 11, wherein determining whether the receiver receives the signal of the unload request further comprises:
determining whether a visual signal of the status light conforms to the signal of the unload request;
confirming the receiver receiving the signal of the unload request if the visual signal of the status light conforms to the signal of the unload request; and
issuing an alarm if the visual signal of the status light does not conform to the signal of the unload request.

13. The method of claim 9, wherein determining whether there is any abnormal condition in the load port is performed after determining whether the receiver receives the signal of the unload request.

14. The method of claim 9, wherein determining whether there is any abnormal condition in the load port further comprises processing the image of the load port.

15. The method of claim 14, wherein determining whether there is any abnormal condition in the load port further comprises:
determining whether the image of the load port comprises a foreign object;
confirming there is no abnormal condition in the load port if there is no foreign object within a range of the load port; and
issuing an alarm if there is the foreign object within a range of the load port.

16. The method of claim 9, further comprising permitting the handling device to pick a material box from the load port performed after determining whether there is any abnormal condition in the load port.

17. An automatic handling system, comprising:
a production equipment comprising a load port and a status light disposed on the load port and configured to display a plurality of visual signals, wherein the visual signals comprise an allowable-to-load signal, an unallowable-to-load signal, an allowable-to-unload signal, and an unallowable-to-unload signal;
a handling device comprising an image capturing device configured to capture an image of the load port; and
a processing unit electrically or communicatively connected to the production equipment and the handling device, wherein the processing unit is configured to:
control the handling device to move forward to the load port of the production equipment;
receive a signal of a load request or an unload request by a receiver of the handling device;
control the image capturing device of the handling device to capture the image of the load port;
determine whether the receiver receives the signal of the load request or the unload request; and
determine whether there is any abnormal condition in the load port.

18. The automatic handling system of claim 17, wherein the handling device further comprises:
a main body, wherein the image capturing device is disposed on the main body; and
a clamping portion connected to the main body and configured to clamp a material box.

19. The automatic handling system of claim 17, wherein the processing unit is further configured to:
determine whether the visual signals of the status light conform to the signal of the load request or the unload request;
confirm the receiver receiving the signal of the load request or the unload request if the visual signals of the status light conform to the signal of the load request or the unload request; and
issue an alarm if the visual signals of the status light do not conform to the signal of the load request or the unload request.

20. The automatic handling system of claim 17, wherein the processing unit is further configured to:
determine whether the image of the load port comprises a foreign object;
confirm there is no abnormal condition in the load port if there is no foreign object within a range of the load port; and
issue an alarm if there is the foreign object within a range of the load port.
